(19) United States
(12) Patent Application Publication
(10) Pub. No.: US 2016/0190011 A1
(43) Pub. Date: Jun. 30, 2016

(54) EPITAXIAL STRUCTURE AND PROCESS THEREOF FOR FORMING FIN-SHAPED FIELD EFFECT TRANSISTOR

(71) Applicant: UNITED MICROELECTRONICS CORP., Hsin-Chu City (TW)

(72) Inventors: Jhen-Cyuan Li, New Taipei City (TW); Shui-Yen Lu, Tainan City (TW)

(21) Appl. No.: 14/608,208

(22) Filed: Jan. 29, 2015

(30) Foreign Application Priority Data
Dec. 26, 2014 (TW) 103145831

(51) Int. Cl. H01L 21/8234; H01L 21/311; H01L 21/762; H01L 23/29; H01L 29/06; H01L 27/088; H01L 23/31; H01L 21/02; H01L 29/78

(52) U.S. Cl. CPC H01L 21/823431; H01L 21/0217; H01L 21/02167; H01L 21/0214; H01L 21/31111; H01L 21/76224; H01L 29/7851; H01L 29/0653; H01L 27/0886; H01L 23/3171; H01L 23/291; H01L 21/823481

(57) ABSTRACT

An epitaxial process includes the following step for forming a fin-shaped field effect transistor. A plurality of fin structures are formed on a substrate and a passivation layer is formed on the substrate between the fin structures. An epitaxial structure is formed on each of the fin structures. The present invention also provides an epitaxial structure formed by said epitaxial process. The epitaxial structure includes a plurality of fin structures, a passivation layer and an epitaxial structure. The fin structures are located on a substrate. The passivation layer is disposed on the substrate between the fin structures. The epitaxial structure is disposed on each of the fin structures.

### BACKGROUND OF THE INVENTION

1. Field of the Invention

The present invention relates generally to an epitaxial structure and process thereof for forming a fin-shaped field effect transistor, and more specifically to an epitaxial structure and process thereof for forming a fin-shaped field effect transistor, which forms a passivation layer to restrain the growing range of the epitaxial structure.

2. Description of the Prior Art

In integrate circuit processes, Fin-shaped field effect transistor (FinFET) devices are extremely important electronic devices. With increasing miniaturization of semiconductor devices, various Fin-shaped field effect transistor (FinFET) devices have been developed. The Fin-shaped field effect transistor (FinFET) is advantageous for the following reasons. First, manufacturing processes of Fin-shaped field effect transistor (FinFET) devices can be integrated into traditional logic device processes, and thus are more compatible. In addition, since the three-dimensional structure of the FinFET increases the overlapping area between the gate and the substrate, the channel region is controlled more effectively. This therefore reduces drain-induced barrier lowering (DIBL) effect and short channel effect. Moreover, the channel region is longer for the same gate length. Therefore, the current between the source and the drain is increased.

On the other hand, chip manufacturers have made metal-oxide-semiconductor (MOS) transistors faster by making them smaller for decades. As the semiconductor processes advance to very deep sub micron era such as 65-nm node or beyond, how to increase the driving current for MOS transistors has become a critical issue. In order to improve device performance, crystal strain technology has been developed. Crystal strain technology is becoming more and more attractive as a means for getting better performance in the field of MOS transistor fabrication. Putting a strain on a semiconductor crystal alters the speed at which charges move through that crystal. Strain makes MOS transistors work better by enabling electrical charges, such as electrons, to pass more easily through the silicon lattice of the gate channel. For the known arts, attempts have been made to use a strained silicon layer, which has been grown epitaxially on a silicon substrate with a silicon germanium (SiGe) layer or silicon carbide (SiC) disposed therebetween. In this type of MOS transistor, a biaxial tensile/compressive strain occurs in the epitaxy silicon layer due to the silicon germanium/silicon carbide which has a larger/smaller lattice constant than silicon, and, as a result, the band structure alters, and the carrier mobility increases. This enhances the speed performance of the MOS transistors.

### SUMMARY OF THE INVENTION

The present invention provides an epitaxial structure and process thereof for forming a fin-shaped field effect transistor, which forms a passivation layer on a substrate between fin structures to control volumes, shapes and growing range of epitaxial structures on the fin structures.

The present invention provides an epitaxial process including the following step for forming a fin-shaped field effect transistor. A plurality of fin structures are formed on a substrate and a passivation layer is formed on the substrate between the fin structures. An epitaxial structure is formed on each of the fin structures.

The present invention provides an epitaxial structure for forming a fin-shaped field effect transistor. The epitaxial structure includes a plurality of fin structures, a passivation layer and an epitaxial structure. The fin structures are located on a substrate. The passivation layer is disposed on the substrate between the fin structures. The epitaxial structure is disposed on each of the fin structures.

According to the above, the present invention provides an epitaxial structure and process thereof for forming a fin-shaped field effect transistor, which forms a plurality of fin structures on a substrate and a passivation layer on the substrate between the fin structures, and then forms an epitaxial structure in the passivation layer and on each of the fin structures. By doing this, the present invention can control volumes, heights and shapes etc of the epitaxial structures by adjusting the height of the passivation layer. Therefore, increasing stresses induced by the epitaxial structures, preventing short circuits caused by the epitaxial structures connecting to each other, and enhancing electrical performances of formed semiconductor devices such as transistors.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-3 schematically depict a three dimensional diagram of an epitaxial process for forming a fin-shaped field effect transistor according to a first preferred embodiment of the present invention.

FIGS. 4-9 schematically depict a cross-sectional view of an epitaxial process for forming a fin-shaped field effect transistor according to a first preferred embodiment of the present invention.

FIG. 10 schematically depicts a three dimensional diagram of an epitaxial process for forming a fin-shaped field effect transistor according to a second preferred embodiment of the present invention.

### DETAILED DESCRIPTION

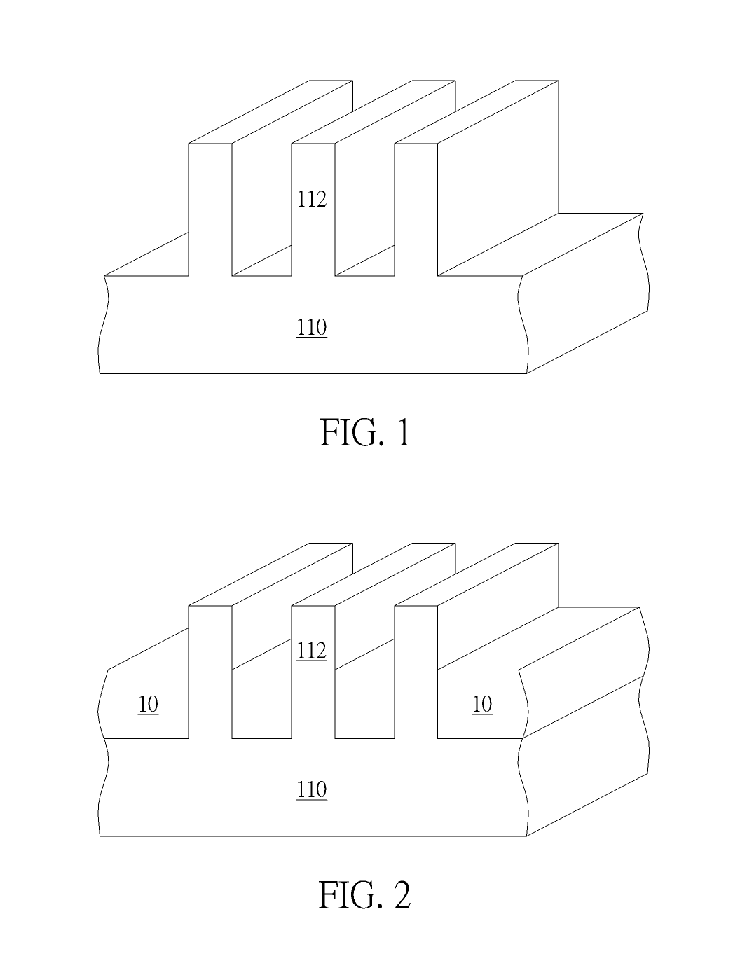

FIGS. 1-3 schematically depict a three dimensional diagram of an epitaxial process for forming a fin-shaped field effect transistor according to a first preferred embodiment of the present invention. As shown in FIG. 1, a plurality of first fin structures 112 are formed on a substrate 110. The substrate 110 may be a semiconductor substrate such as a silicon substrate, a silicon containing substrate, a III-V group-on-silicon (such as GaN-on-silicon) substrate, a graphene-on-silicon substrate or a silicon-on-insulator (SOI) substrate. The method of forming the first fin structures 112 on the substrate 110 may include, but not limited to, the following step. The number of the first fin structures 112 is not restricted to three as depicted in the figures.

A bulk bottom substrate (not shown) is provided. A hard mask layer (not shown) is formed on the bulk bottom substrate (not shown) and is patterned to define the location of the first fin structures 112, which will be formed in the bulk bottom substrate (not shown). An etching process is performed to form the first fin structures 112 in the bulk bottom substrate (not shown). Thus, the first fin structures 112 located on the substrate 110 are formed completely. In one embodiment, the hard mask layer (not shown) is removed after the first fin structures 112 are formed, and a tri-gate MOSFET can be formed in the following processes. There are three contact faces between the first fin structures 112 and the following formed dielectric layer functioning as a carrier channel whose width is wider than a channel width in a conventional planar MOSFET. When a driving voltage is applied, the tri-gate MOSFET produces a double on-current comparing to the conventional planar MOSFET. In another embodiment, the hard mask layer (not shown) is reserved to forma fin field effect transistor (Fin FET), which is another kind of multi-gate MOSFET. Due to the hard mask layer (not shown) being reserved in the fin field effect transistor, there are only two contact faces between the first fin structures 112 and the following formed dielectric layer.

The present invention can also be applied to other semiconductor substrates. For example, a silicon-on-insulator substrate (not shown) is provided, and then a single crystalline silicon layer being a top part of the silicon-on-insulator substrate (not shown) is etched till an oxide layer being a middle part of the silicon-on-insulator substrate (not shown) is exposed, meaning the fin-shaped structure formed on the silicon-on-insulator substrate (not shown) is finished.

As shown in FIG. 2, an isolation structure 10 may be formed on the substrate 110 between the first fin structures 112 to electrically isolate transistors later disposed across the first fin structures 112. The isolation structure 10 may be a shallow trench isolation (STI) structure, which may be formed by a shallow trench isolation (STI) process, but it is not limited thereto.

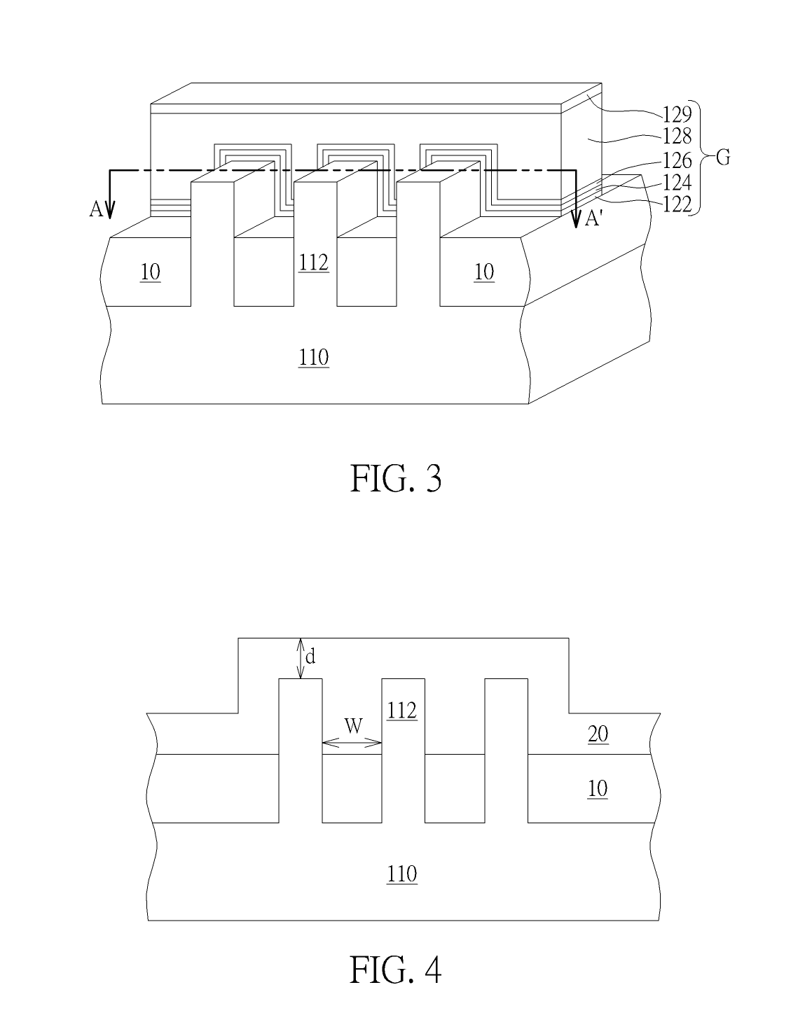

As shown in FIG. 3, a gate structure G may be formed across the substrate 110 and the first fin structures 112. The method of forming the gate structure G may include, but not limited to, the following step. A buffer layer (not shown), a gate dielectric layer (not shown), a barrier layer (not shown), an electrode layer (not shown) and a cap layer (not shown) are formed from bottom to top to cover the first fin structures 112 and the substrate 110; then, the cap layer (not shown), the electrode layer (not shown), the barrier layer (not shown), the gate dielectric layer (not shown) and the buffer layer (not shown) are patterned to form a buffer layer 122, a gate dielectric layer 124, a barrier layer 126, an electrode layer 128 and a cap layer 129 on the substrate 110. Thereby, the gate structure G being a stacked structure including the buffer layer 122, the gate dielectric layer 124, the barrier layer 126, the electrode layer 128 and the cap layer 129 is formed.

The buffer layer 122 may be an oxide layer, which may be formed by a thermal oxide process or a chemical oxide process, but it is not limited thereto. The buffer layer 122 is located between the gate dielectric layer 124 and the substrate 110 for buffering the gate dielectric layer 124 and the substrate 110. In this embodiment, a gate-last for high-K first process is applied. Thus, the gate dielectric layer 124 may be a dielectric layer having a high dielectric constant, such as the group selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalite (SrBi₂Ta₂O₉, SBT), lead zirconate titanate (PbZrₓTi₁-xO₃, PZT) and barium strontium titanate (BaₓSr₁-xTiO₃, BST), but it is not limited thereto. In another embodiment, as a gate-last for high-K last process is applied, the gate dielectric layer 124 will be removed and a dielectric layer having a high dielectric constant will be filled, therefore the gate dielectric layer 124 can be composed of a sacrificial material suited for being removed in later processes. The barrier layer 126 is located on the gate dielectric layer 124 for serving as an etch stop layer to protect the gate dielectric layer 124 and prevent above metals from diffusing downward to the gate dielectric layer 124 while the sacrificial electrode layer 128 is removed. The barrier layer 126 may be a single layer structure or a multilayer structure composed of tantalum nitride (TaN), titanium nitride (TiN) or etc. The electrode layer 128 may be composed of polysilicon, which will be replaced by a metal gate in later processes, but it is not limited thereto. The cap layer 129 may be a single layer structure, a multilayer structure composed of silicon nitride or silicon oxide etc. for serving as a patterned hard mask, but it is not limited thereto.

FIGS. 4-9 is a processing step following the processing step of FIGS. 1-3. For clarifying the present invention, FIGS. 4-9 schematically depict a cross-sectional view along AA′ line of FIG. 3. It is noted that, due to the gate structure G being already formed, a passivation layer and an epitaxial structure formed in the following are just located beside the gate structure G, but without being located right beneath the gate structure G.

As shown in FIG. 4, a passivation material 20 fills between the first fin structures 112. The passivation material 20 may be composed of silicon nitride, carbon containing silicon nitride or carbon and oxygen containing silicon nitride etc, which must be able to restrain later formed epitaxial structures. In this embodiment, the passivation material 20 blanketly covers the substrate 110 and the first fin structures 112. It is emphasized that, the passivation material 20 of the present invention must fill up spaces between the first fin structures 112 for preventing the later formed epitaxial structures from being formed between the first fin structures 112. Hence, a height d of each of the first fin structures 112 higher than that of the passivation material 20 is preferably larger than or equal to a half of a width w between the first fin structures 112, to ensure the passivation material 20 fills up spaces between the first fin structures 112.

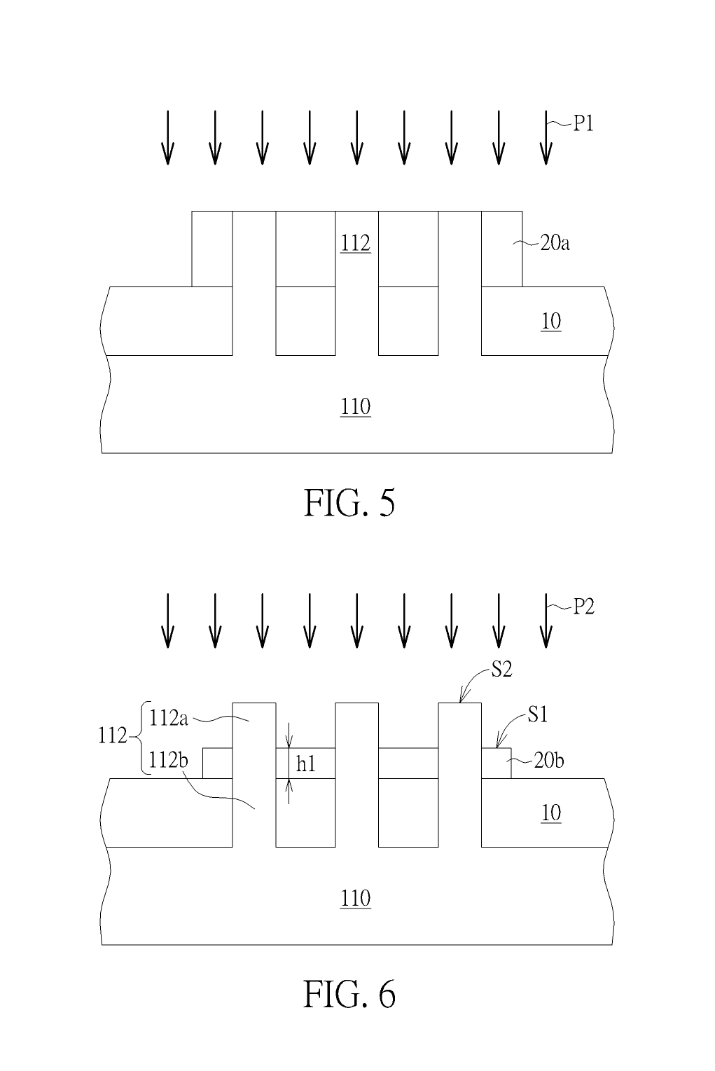

As shown in FIGS. 5-6, the passivation material 20 may be etched to form a passivation layer 20b and expose the first fin structures 112, wherein the passivation layer 20b is directly on the isolation structure 10. In this embodiment, the passivation material 20 may be etched by two processes. That is, a main etching process P1 may be performed followed by an over-etching process P2, but it is not limited thereto. In another embodiment, the passivation material 20 may be etched just by a single process to form the passivation layer 20b; or, the passivation material 20 may be etched by three or more than three processes to form the passivation layer 20b.

More precisely, as shown in FIG. 5, the passivation material 20 may be etched by the main etching process P1 firstly until the first fin structures 112 are exposed, thereby a passivation material 20a being formed. In this embodiment, the passivation material 20 is etched by the main etching process P1 until the passivation material 20 is trimmed with the first fin structures 112. For increasing the efficiency of etching, the main etching process P1 is preferred to have a higher etching rate, or have non-etching selectivity to the first fin structures 112, the passivation material 20 and other material layers; that is, the main etching process P1 has the same etching rate as the first fin structures 112, the passivation material 20 and other material layers.

Thereafter, the over-etching process P2 is performed to form a passivation layer 20b after the passivation material 20 is etched by the main etching process P1 until the first fin structures 112 are exposed, as shown in FIG. 6. By doing this, a top surface S1 of the passivation layer 20b is lower than top surfaces S2 of the first fin structures 112. Moreover, a height h1 of the passivation layer 20b can be controlled by the over-etching process P2, so that growing heights of bottom parts of later formed epitaxial structures can be controlled and top parts of the epitaxial structures can be prevented from connecting to each other, which leads to short circuits. On the other hand, the top surface S1 of the passivation layer 20b can have a flat top surface by using the over-etching process P2, hence the later formed epitaxial structures can have common heights, and same growing ranges. In this embodiment, the over-etching process P2 has a high selectivity to the passivation layer 20b and the first fin structures 112; that is, the over-etching process P2 has an etching rate to the passivation layer 20b larger than that of the first fin structures 112, so that the top surface S1 of the passivation layer 20b is lower than the top surfaces S2 of the first fin structures 112.

Since the main etching process P1 and the over-etching process P2 have different etching purposes, the etching rates of the main etching process P1 and the over-etching process P2 to the first fin structures 112 and the passivation layer 20b are preferably different. For instance, for increasing etching efficiency, the main etching process P1 should have higher etching rates to the first fin structures 112 and the passivation layer 20b and the etching rate to the first fin structures 112 should be common to the etching rate to the passivation layer 20b. Furthermore, for controlling the height h1 and the uniformity of the passivation layer 20b and enabling the top surface S1 of the passivation layer 20b to be lower than the top surfaces S2 of the first fin structures 112, the over-etching process P2 should have lower etching rates to the first fin structures 112 and the passivation layer 20b and the etching rate to the passivation layer 20b should be larger than the etching rate to the first fin structures 112, but it is not limited thereto.

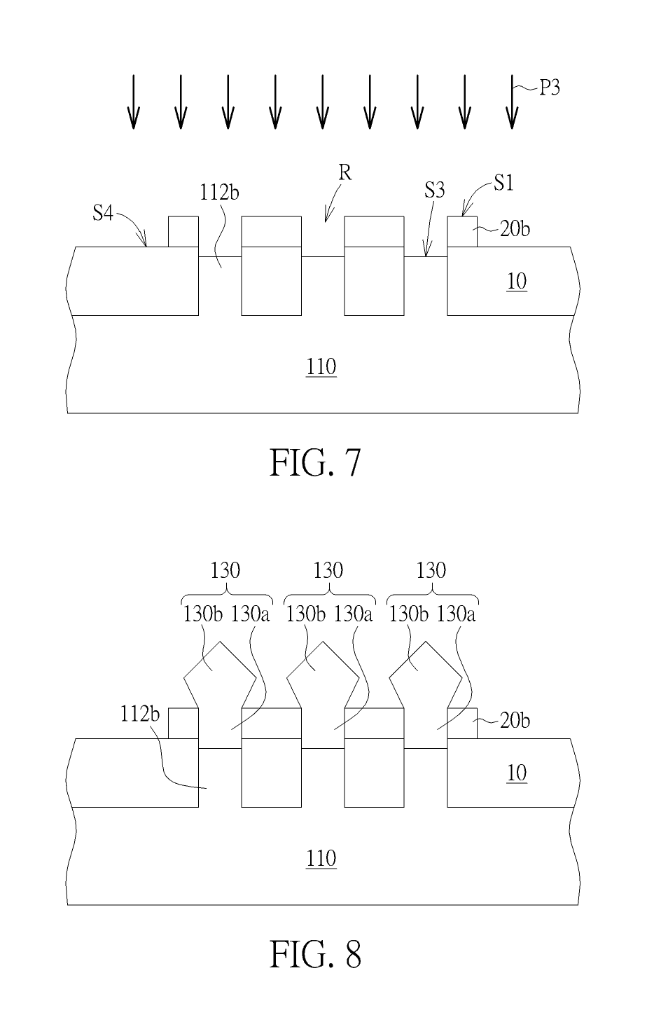

Top parts 112a of the first fin structures 112 may be removed to form fin structures 112b and to form a plurality of recesses R in the passivation layer 20b, enabling later formed epitaxial structures to be formed in the recesses R, as shown in FIG. 7. By doing this, the top surface S1 of the passivation layer 20b is higher than top surfaces S3 of the fin structures 112b. The method of removing the top parts 112a of the first fin structures 112 may include, but not limited to, the following. An etching process P3 having a higher etching rate to the first fin structures 112 than to the passivation layer 20b may be performed, so that the top parts 112a of the first fin structures 112 can be removed while the passivation layer 20b is reserved. In this embodiment, the top surfaces S3 of the fin structures 112b are lower than a top surface S4 of the isolation structure 10, to increase volumes of later formed epitaxial structures, but it is not limited thereto. In other cases, the top surfaces S3 of the fin structures 112b may be higher than or equal to the top surface S4 of the isolation structure 10.

As shown in FIG. 8, an epitaxial structure 130 is formed on each of the fin structures 112b. In other words, the epitaxial structures 130 grow on the fin structures 112b and in the recesses R of the passivation layer 20b. The epitaxial structures 130 may be silicon germanium epitaxial structures, silicon carbide epitaxial structures or silicon phosphorous epitaxial structures etc, depending upon electrical types or practical requirements of formed transistors. For example, as the epitaxial structures 130 are formed, phosphorous ions can be highly doped in-situ to form silicon phosphorous epitaxial structures, but it is not limited thereto. Moreover, lightly doped source/drain (not shown) and source/drain (not shown) may be formed in the fin structures 112b and the epitaxial structures 130 before, after or while the epitaxial structures 130 are formed.

It is emphasized that, the epitaxial structures 130 must be grown from the silicon fin structures 112b, and thus can not be grown on the passivation layer 20b. Therefore, volumes, shapes and heights etc of the epitaxial structures 130 can be controlled by adjusting the height of the passivation layer 20b, or even the recesses R of the passivation layer 20b in the present invention. Thereby, increasing stresses induced by the epitaxial structures 130, preventing short circuits caused by the epitaxial structures 130 connecting to each other, and enhancing the electrical performances of formed semiconductor devices such as transistors. In this embodiment, the epitaxial structures 130 have bottom parts 130a in the passivation layer 20b and top parts 130b protruding from the passivation layer 20b, wherein the top parts 130b shadow a part of the passivation layer 20b. By doing this, volumes of the epitaxial structures 130 can be increased to increase induced stresses and prevent the top parts 130b protruding from the passivation layer 20b from connecting to each other caused by too large volumes.

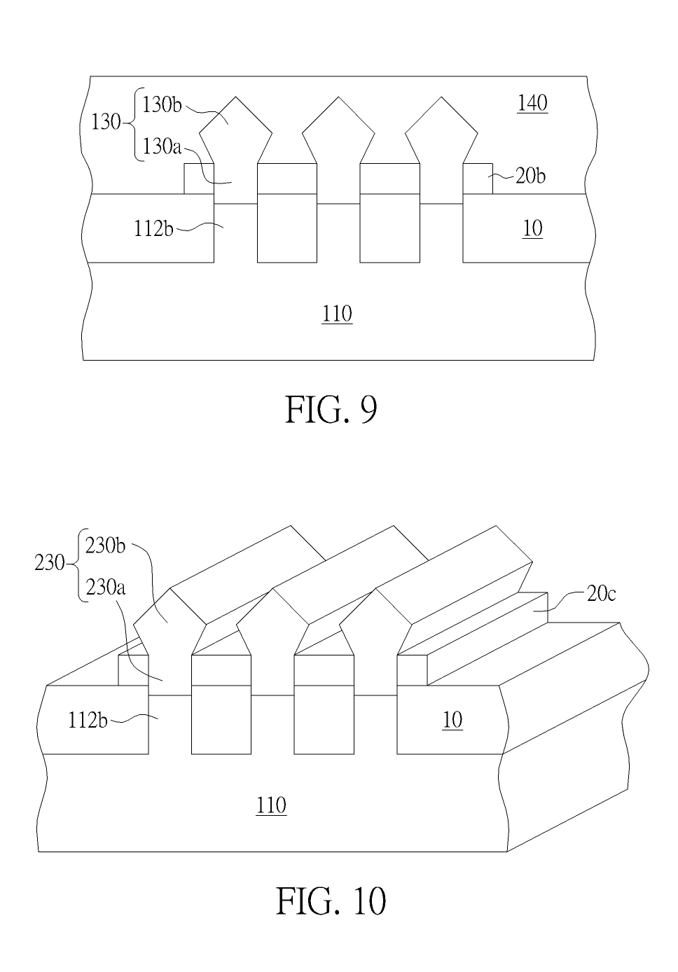

As shown in FIG. 9, a dielectric layer 140 may be formed to blanketly cover the epitaxial structures 130 and the passivation layer 20b. In this embodiment, the dielectric layer 140 is an interdielectric layer, but it is not limited thereto.

According to the above, the gate structure G of FIG. 3 is formed and then the passivation layer 20b and the epitaxial structures 130 are formed, thereby the passivation layer 20b and the epitaxial structures 130 being formed only beside the gate structure G. However, the present invention can also applied to another case, which forms the passivation layer 20b and the epitaxial structures 130 and then forms the gate structure G. Please refer to FIG. 10, after the step of FIG. 2: the isolation structure 10 is formed on the substrate 110 between the fin structures 112, the method of FIGS. 4-8 is rightly performed, which blanketly forms a passivation layer 20c directly on the isolation structure 10, and forms rod epitaxial structures 230 in the passivation layer 20c and the fin structures 112b. Thereafter, a gate structure (not shown) is formed on the epitaxial structures 230, the passivation layer 20c and the fin structures 112b. In this embodiment, the main etching process P1 of FIG. 5 may be replaced by a planarization process such as a chemical mechanical polishing (CMP) process, but it is not limited thereto.

The passivation layer 20c may be silicon nitride, carbon containing silicon nitride or carbon and oxygen containing silicon nitride, but it is not limited thereto. The epitaxial structures 230 may be silicon germanium epitaxial structures, silicon carbide epitaxial structures or silicon phosphorous epitaxial structures etc, depending upon electrical types or practical requirements of formed transistors. For example, as the epitaxial structures 230 are formed, phosphorous ions can be highly doped in-situ to form silicon phosphorous epitaxial structures, but it is not limited thereto.

It is emphasized that, the epitaxial structures 230 must be grown from the silicon fin structures 112b, and thus can not be grown on the passivation layer 20c. Therefore, volumes, shapes and heights etc of the epitaxial structures 230 can be controlled by adjusting the height of the passivation layer 20c, or even the recesses of the passivation layer 20c in the present invention. Thereby, increasing stresses induced by the epitaxial structures 230, preventing short circuits caused by the epitaxial structures 230 connecting to each other, and enhancing the electrical performances of formed semiconductor devices such as transistors. In this embodiment, the epitaxial structures 230 have bottom parts 230a in the passivation layer 20c and top parts 230b protruding from the passivation layer 20c, wherein the top parts 230b shadow a part of the passivation layer 20c. By doing this, volumes of the epitaxial structures 230 can be increased to increase induced stresses and prevent the top parts 230b protruding from the passivation layer 20c from connecting to each other caused by too large volumes.

It is noted that, in this embodiment, the epitaxial structures 230 are formed followed by the gate structure (not shown) disposed across the epitaxial structure 230 and the passivation layer 20c, and a lightly doped source/drain (not shown) and a source/drain (not shown) may be formed in the epitaxial structures 230; and then, a dielectric layer (not shown) may be formed to blanketly cover the gate structure, the epitaxial structures 230 and the passivation layer 20c, and so on.

To summarize, the present invention provides an epitaxial structure and process thereof for forming a fin-shaped field effect transistor, which forms a plurality of fin structures on a substrate and a passivation layer on the substrate between the fin structures, and then forms an epitaxial structure in the passivation layer and each of the fin structures. By doing this, the present invention can control volumes, heights and shapes etc of the epitaxial structures by adjusting the height of the passivation layer. Therefore, increasing stresses induced by the epitaxial structures, preventing short circuits caused by the epitaxial structures connecting to each other, and enhancing electrical performances of formed semiconductor devices such as transistors.

Furthermore, since the epitaxial structures must be grown on the silicon fin structures, but can not be formed on the passivation layer, the passivation layer may be preferably composed of silicon nitride, carbon containing silicon nitride or carbon and oxygen containing silicon nitride etc. The method of forming the passivation layer may include: forming a plurality of first fin structures on the substrate, filling a passivation material between the first fin structures, and then etching the passivation material to form a passivation layer but exposing the first fin structures; then, top parts of the first fin structures may be removed according to practical requirements to have spaces for the epitaxial structures formed therein. Moreover, the passivation material may be etched several times. For example, the main etching process may be performed to etch the passivation material until the first fin structures are exposed, and then an over-etching process may be performed to form the passivation layer, which has a top surface lower than that of the first fin structures, but it is not limited thereto.

Those skilled in the art will readily observe that numerous modifications and alterations of the device and method may be made while retaining the teachings of the invention. Accordingly, the above disclosure should be construed as limited only by the metes and bounds of the appended claims.

1. An epitaxial process used for forming a fin-shaped field effect transistor, comprising:
forming a plurality of fin structures on a substrate and forming a passivation layer on the substrate between the fin structures; and
forming an epitaxial structure on each of the fin structures.

2. The epitaxial process according to claim 1, wherein a top surface of the passivation layer is higher than top surfaces of the fin structures.

3. The epitaxial process according to claim 2, wherein the top surface of the passivation layer has a flat top surface.

4. The epitaxial process according to claim 1, wherein the passivation layer comprises silicon nitride, carbon containing silicon nitride or carbon and oxygen containing silicon nitride.

5. The epitaxial process according to claim 1, wherein the step of forming the fin structures on the substrate and forming the passivation layer on the substrate between the fin structures comprises:
forming a plurality of first fin structures on the substrate;
filling a passivation material between the first fin structures; and
etching the passivation material to form the passivation layer but exposing the first fin structures.

6. The epitaxial process according to claim 5, wherein the method of etching the passivation material comprises performing a main etching process and an over-etching process.

7. The epitaxial process according to claim 6, wherein the main etching process is performed to etch the passivation material until the first fin structures are exposed, and then the over-etching process is performed to form the passivation layer, wherein the passivation layer has a top surface lower than top surfaces of the first fin structures.

8. The epitaxial process according to claim 6, wherein the etching rate of the main etching process is different from the etching rate of the over-etching process.

9. The epitaxial process according to claim 5, further comprising:
removing top parts of the first fin structures after the passivation layer is formed, to form the fin structures and to form a plurality of recesses in the passivation layer, enabling the epitaxial structure to be formed in each of the recesses.

10. The epitaxial process according to claim 1, further comprising:
forming an isolation structure between the fin structures before the passivation layer is formed, so that the fin structures are isolated from each other and the passivation layer is directly on the isolation structure.

11. An epitaxial structure used for forming a fin-shaped field effect transistor, comprising:
a plurality of fin structures located on a substrate;
a passivation layer disposed on the substrate between the fin structures; and
an epitaxial structure disposed on each of the fin structures, wherein each of the epitaxial structures comprises a bottom part and a top part, wherein the bottom part is located in the passivation layer while the top part protrudes from the passivation layer, and sidewalls of the bottom parts trim sidewalls of the fin structures.

12. The epitaxial structure according to claim 11, wherein a top surface of the passivation layer is higher than top surfaces of the fin structures.

13. The epitaxial structure according to claim 12, wherein the top surface of the passivation layer has a flat top surface.

14. The epitaxial structure according to claim 11, wherein the passivation layer comprises silicon nitride, carbon containing silicon nitride or carbon and oxygen containing silicon nitride.

15. The epitaxial structure according to claim 11, wherein the epitaxial structure protrudes from the passivation layer.

16. (canceled)

17. The epitaxial structure according to claim 16, wherein the top parts of the epitaxial structures shadow a part of the passivation layer.

18. The epitaxial structure according to claim 11, further comprising:
an isolation structure disposed between the fin structures, so that the fin structures are isolated from each other.

19. The epitaxial structure according to claim 18, wherein the passivation layer is directly on the isolation structure.

20. The epitaxial structure according to claim 11, further comprising:
a dielectric layer covering the epitaxial structures and the passivation layer.
